(19) United States
(12) Patent Application Publication
(10) Pub. No.: US 2003/0119272 A1
(43) Pub. Date: Jun. 26, 2003

(54) Semiconductor device and method for forming the same

(76) Inventor: Ga Won Lee, Kyoungki-do (KR)

Correspondence Address: JACOBSON HOLMAN PLLC, 400 SEVENTH STREET N.W., SUITE 600, WASHINGTON, DC, 20004, US

(21) Appl. No.: 10/327,857

(22) Filed: Dec. 26, 2002

(30) Foreign Application Priority Data
Dec. 26, 2001 (KR) 2001-84905
Nov. 30, 2002 (KR) 2002-75615

(51) Int. Cl. H01L 21/20

(52) U.S. Cl. 438/381

(57) ABSTRACT

The present invention discloses a capacitor of a semiconductor device and a method for forming the same which has sufficient capacitance for high integration of the semiconductor device. A stack structure of a first capacitor and a second capacitor is formed to be connected to a semiconductor substrate. Here, the first and second capacitors are vertically spaced apart and electrically insulated from each other, and the adjacent capacitors are formed on different layers. Accordingly, sufficient capacitance for high integration of the semiconductor device is obtained to improve reliability of the semiconductor device and achieve high integration thereof.

### BACKGROUND OF THE INVENTION

1. Field of the Invention

The present invention relates to a semiconductor device comprising capacitors and a method for forming the same, and in particular to a semiconductor device comprising capacitors and a method for forming the same which provide increased projection area of a cell capacitor ranging from 3F² to 12F² by forming a multi stack type capacitor.

2. Description of the Background Art

One of the important factor in the embodiment of giga level DRAMs is to form a capacitor provides sufficient capacitance for high integration.

In particular, in the DRAM wherein a unit cell includes a MOS transistor and a capacitor, a capacitance of the capacitor needs to be increased and an area occupied by the capacitor needs to be decreased to achieve high integration.

Therefore, in order to increase the capacitance of the capacitor which follows the equation (Eo×Er×A)/T (where Eo denotes a vacuum dielectric constant, Er denotes a dielectric constant of a dielectric film, A denotes an area of the capacitor and T denotes a thickness of the dielectric film), a method of increasing a surface area of a storage node which is a lower electrode has been proposed.

The capacitance required for reading stored information is 25 to 30fF per cell regardless of DRAM generation. However, an area of region allocated for capacitors has been reduced due to increase of an integration density of the DRAM.

The foregoing problem is in a giga level DRAM region. Researches have been made on structures of the capacitor and development of insulating film materials for increasing the capacitance.

Factors for determining the capacitance of the DRAM include an area of a capacitor, a dielectric constant of a dielectric material and an equivalent oxide thickness (EOT).

FIG. 1 is a layout view illustrating a conventional semiconductor device, wherein a general 5F² folded bit line structure DRAM cell is shown as an example. Here, F denotes ts a minimum pitch size.

5F by 1F rectangular active regions 12 are alternately arranged on a semiconductor substrate 10. Word lines 14 having a width of 1F are arranged vertical to the active regions 12 at an interval of 1F. Capacitors 16 having a length of 3F are formed at both sides of one active region 12. Here, the capacitors 16 are electrically connected to the semiconductor substrate 10 through contacts 18.

FIG. 2 is a graph showing accumulated electric charges according to a height of a storage node and an EOT. The graph illustrates the storage node height and the EOT of the capacitor required for obtaining the capacitance of 25 to 30fF per cell when the capacitor of FIG. 1 has a simple stacked structure and F is 0.7 nm. A surface area is calculated in consideration of edge rounding effects in a storage node patterning process of the cell.

When an aspect ratio of the storage node height is 10, the EOT must at least be about 0.5 nm, and when the aspect ratio is 20, the EOT must at least be 1 nm in order to form the capacitor having a capacitance of 25 fF. It is thus necessary to use a high dielectric constant material.

However, most of the high dielectric constant materials are difficult to be used in processes.

In particular, when a metal electrode such as Ru is used as a storage node and a plate electrode when a thin film having a high dielectric constant is used. In such cases, characteristics of the device is deteriorated due to thermal budget.

In addition, the characteristics of a high dielectric constant material is degraded in subsequent thermal annealing process, or a gap filling property is degraded due to the high aspect ratio.

### SUMMARY OF THE INVENTION

Accordingly, it is an object of the present invention to provide a capacitor of a semiconductor device which has sufficient capacitance and occupies small area, by forming adjacent capacitors on different layers without increasing the height of a storage node.

Another object of the present invention is to provide a method for forming a capacitor of a semiconductor device which has sufficient capacitance for high integration of the semiconductor device without increasing a storage node height.

In order to achieve the above-described objects of the invention, there is provided a semiconductor device having a folded bit line structure in which a first capacitor and a second capacitor are connected to one active region, wherein the first capacitor and the second capacitor are respectively formed at a different altitude, being electrically isolated from each other.

In addition, the first and the second capacitors are 5F² respectively and overlaps each other by 1F².

According to another aspect of the invention, a capacitor of a semiconductor device includes: a 5F by 1F rectangular active region; two word lines of 1F, running across one active region; and two capacitors in one active region formed at a different altitude with being electrically isolated from each other, wherein the second capacitors have a size of 5F² respectively and overlap by a predetermined size.

Here, the two capacitors overlap each other by F².

According to yet another aspect of the invention, a capacitor of a semiconductor device includes: a 5F by 1F rectangular active region; two word lines of 1F, running across one active region; and two 2F by 6F capacitors connected to one active region, wherein the two capacitors are formed at a different altitude with being electrically isolated and overlap by a predetermined width.

Here, the two capacitors overlap each other by 2F×2F.

According to yet another aspect of the invention, a method for forming a capacitor of a semiconductor device includes the steps of: forming a device isolation oxide film defining active regions on a semiconductor substrate; forming a first interlayer insulating film on the entire surface of the resulting structure; selectively patterning the first interlayer insulating film to form a first and a second contact plugs contact to the active region; forming a third contact plug contacting the second contact plug; forming a first insulating spacer on the sidewalls of the third contact plug, whereby a first contact hole exposing the first contact plug is generated; forming a first capacitor having a storage node, a dielectric film and a plate electrode in the first contact hole; forming a fourth contact plug connected to the plate electrode of the first capacitor on the resultant structure; forming a second insulating spacer on the sidewalls of the fourth contact plug so that the second insulating spacer covers the exposed surface of the first capacitor, whereby a second contact hole exposing the third contact plug is generated; and forming a second capacitor in the second contact hole.

In addition, the method further comprises, after forming the first capacitor, a step of forming a second insulating film on the resultant structure to isolate the first capacitor from the second capacitor.

The principle of the present invention lies in that a multi stacked cell capacitor is provided to increase the capacitance of DRAM.

### BRIEF DESCRIPTION OF THE DRAWINGS

The present invention will become better understood with reference to the accompanying drawings which are given only by way of illustration and thus-are not limitative of the present invention, wherein:

FIG. 1 is a layout view illustrating a conventional semiconductor device;

FIG. 2 is a graph showing accumulated charges according to a height of a storage node height and an equivalent oxide thickness;

FIG. 3 is a layout view illustrating a semiconductor device in accordance with a first embodiment of the present invention;

FIG. 4a is a cross-sectional view taken along line A-A of FIG. 3;

FIG. 4b is a cross-sectional view taken along line B-B of FIG. 3;

FIG. 5 is a layout view illustrating a semiconductor device in accordance with a second embodiment of the present invention;

FIGS. 6a to 6g are cross-sectional views illustrating sequential steps of a method for forming a capacitor in accordance with the present invention;

FIG. 7 is a cross-sectional view illustrating a semiconductor device in accordance with a third embodiment of the present invention.

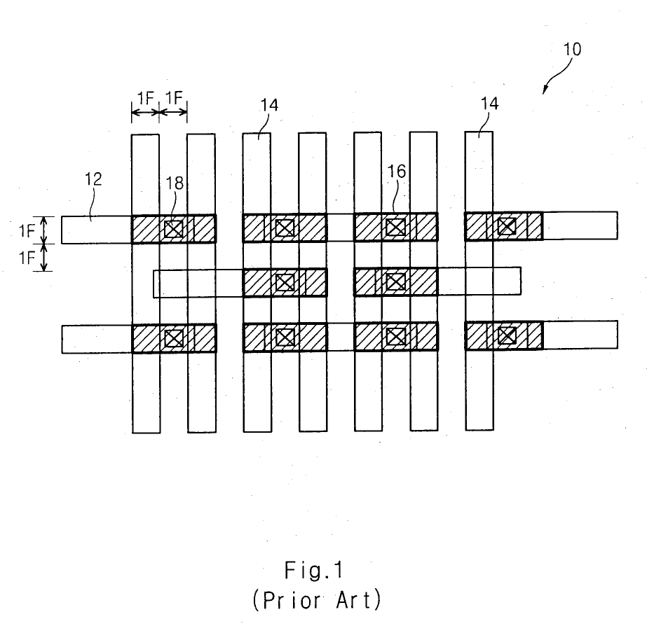

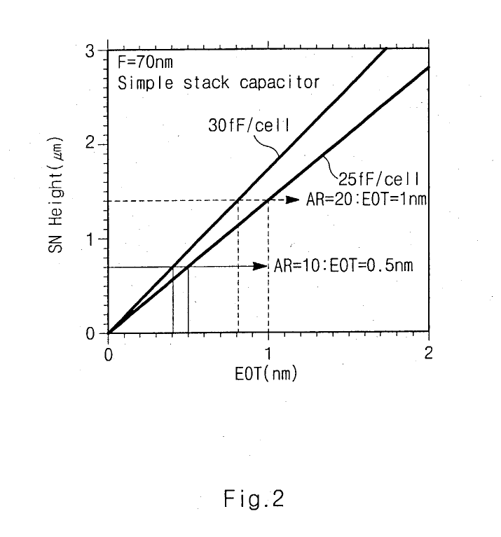

### DETAILED DESCRIPTION OF THE PREFERRED EMBODIMENTS

A capacitor of a semiconductor device and a method for forming the same in accordance with preferred embodiments of the present invention will now be described in detail with reference to the accompanying drawings.

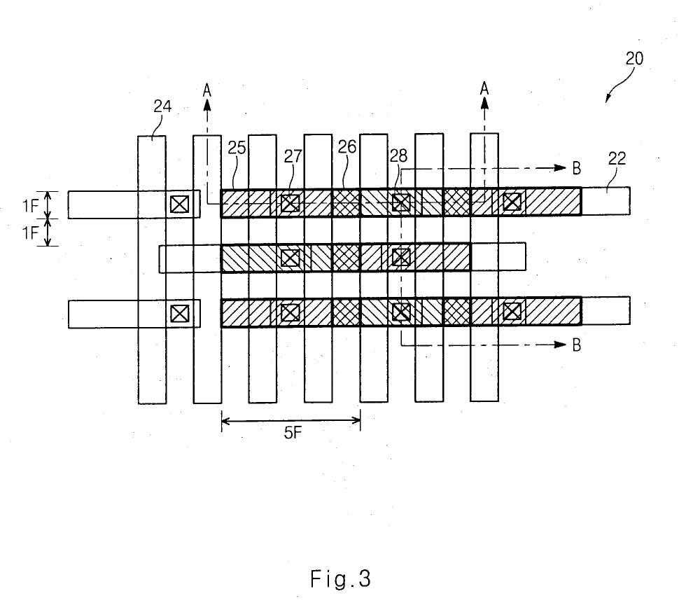

FIG. 3 is a layout view illustrating a semiconductor device in accordance with a first embodiment of the present invention, capacitor having an area of 5F² in a folded bit line structure.

5F by 1F rectangular active regions 22 are arranged on a semiconductor substrate 20 at an interval of 1F. A plurality of word lines 24 are arranged vertical to the active region 22 wherein two word lines cross one active region 22. Two rectangular shaped capacitors 25 and 26 having a width of 1F and a length of 5F are formed on two different layers in one active region 22. Here, the capacitors 25 and 26 are electrically connected to the active region 22 through contacts 27 and 28.

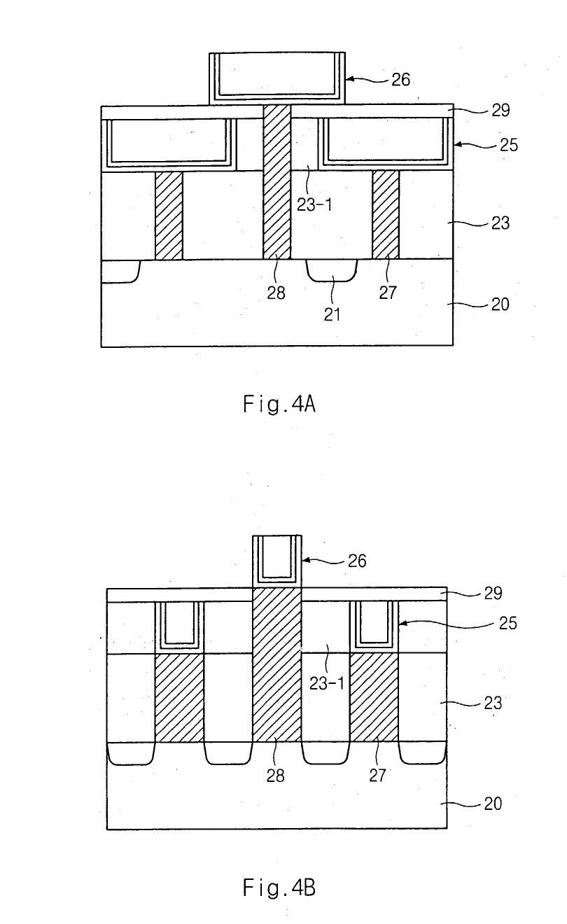

FIGS. 4a and 4b are cross-sectional views illustrating the capacitor, taken along lines A-A and B-B of FIG. 3, wherein a device isolation oxide films and word lines are not shown.

As shown in FIG. 4a, a device isolation oxide film 21 defining the active regions on the semiconductor substrate 20 is formed in a shallow trench type. First capacitors 25 having a size of 1×F² are formed on a first interlayer insulating film 23 to contact the active region 22 through a contact 27 A second interlayer insulating film 23-1 is formed to fill the space between the first capacitors 25, and a third interlayer insulating film 29 is formed on the first capacitor 25 and the second interlayer insulating film 23-1. A second capacitor 26 is formed on the third interlayer insulating film- 29 to contact the active region 22 through a contact 28. Here, the long axis direction end of the second capacitor 26 overlaps with that of the first capacitors 25 by 1F².

As depicted in FIG. 4b, the first and the second capacitors 25 and 26 are formed at a width of 1F to be separated from adjacent capacitors. It should be noted that these capacitors are formed according to conventional damascene and patterning processes.

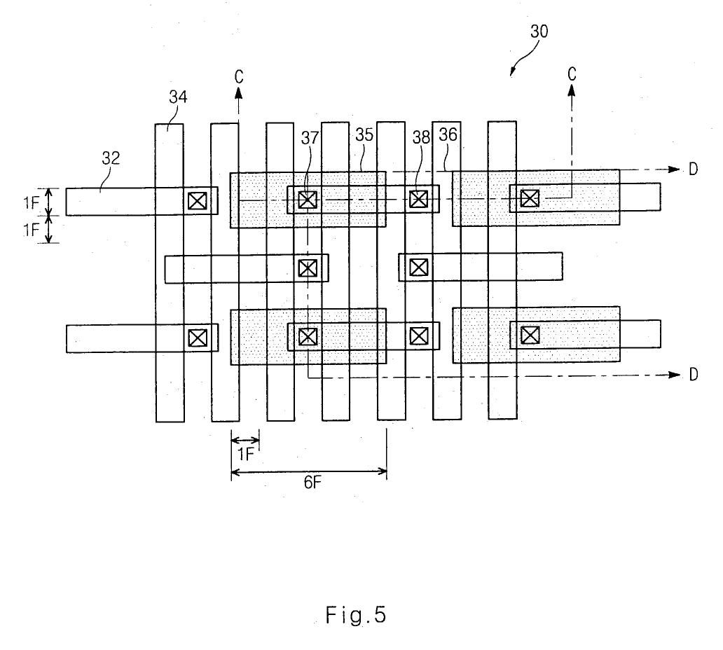

FIG. 5 is a layout view illustrating a semiconductor device in accordance with a second embodiment of the present invention, wherein capacitor has an area of 12F² larger than the capacitor of FIG. 3.

5F by 1F rectangular active regions 32 are arranged on a semiconductor substrate 30 at an interval of 1F. A plurality of word lines 34 are arranged vertical to the active region 22 wherein two word lines cross one active region 32. The first and the second capacitors 35 and 36 having a width of 2F and a length of 6F are formed on two different layers in one active region 32. Here, the first and second capacitors 35 and 36 are electrically connected to the active region 32 through contacts 37 and 38. Sections of the first capacitor 35 and the second capacitor 36 correspond to FIGS. 4a and 4b, but are larger in size.

Since intervals between contact portions of the first capacitors 35 and the second capacitor 36 are less than 1F, conventional patterning processes cannot be used. A process using a spacer is required for patterning.

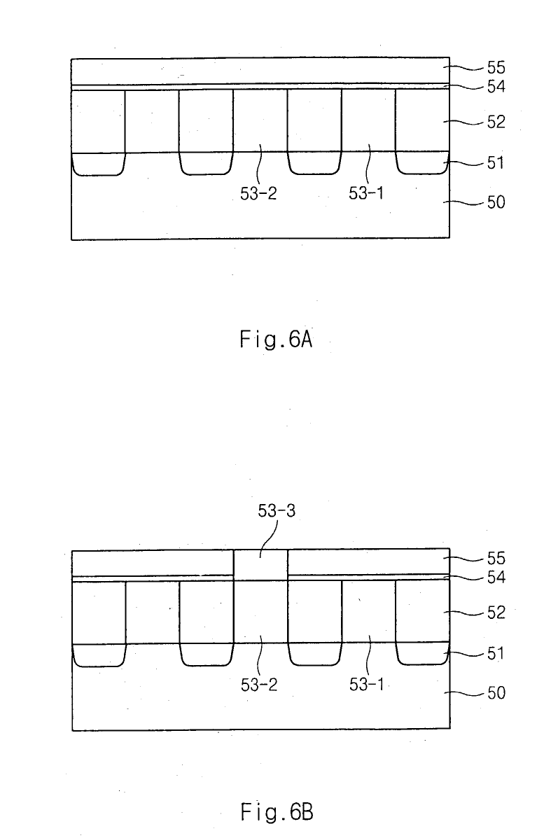

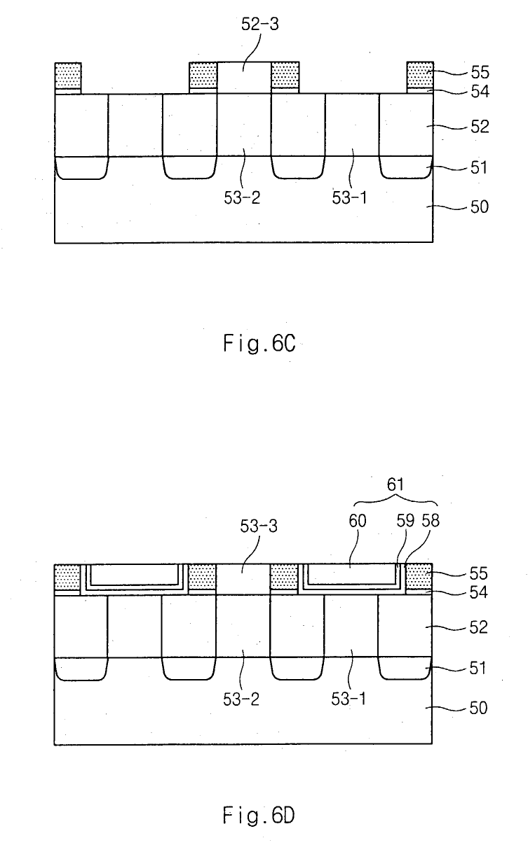

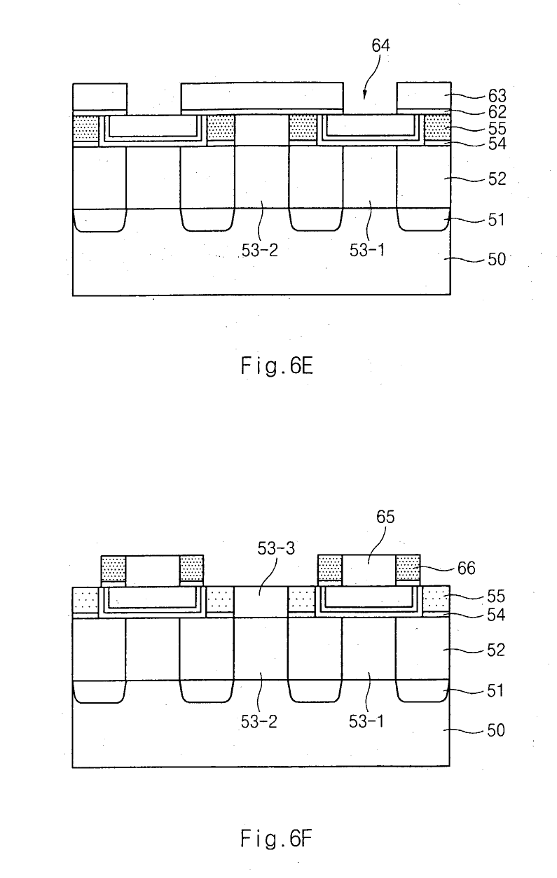

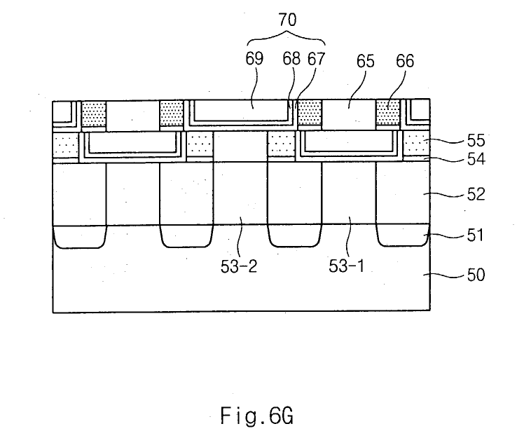

FIGS. 6a to 6g are cross-sectional views illustrating sequential steps of a method for forming a capacitor of FIG. 5 in accordance with the present invention.

Referring to FIG. 6a, a lower structure including active regions (not shown), a device isolation oxide film 51 and a gate electrode (not shown) is formed on a semiconductor substrate 50, preferably a silicon wafer. A first interlayer insulating film 52 including first contact plugs 53-1 and a second contact plugs 53-2 for storage node is formed thereon.

A first etch stop layer 54 and a second interlayer insulating film 55 which are composed of oxide films are sequentially formed on the entire surface of the resulting structure.

As shown in FIG. 6b, a portion of the second interlayer insulating film 55 and a portion of the first etch stop layer 54 are removed to form an opening exposing the second contact plug 53-2, and the opening is then filled with a contact plug material to form a third contact plug 53-3.

As depicted in FIG. 6c, the second interlayer insulating film 55 is removed so that the third contact plug 53-3 protrudes, and a first insulating spacer 57 is then formed on the sidewalls of the third contact plug 53-3. Here, a width of the first insulating spacer is smaller than 1F and larger than 0.5F. When the width of the first insulating spacer 57 is smaller than 0.5F, a short may occur between the adjacent upper and lower capacitors, and when the width of the first insulating spacer 57 is larger than 1F, a size of the adjacent capacitor is reduced. In addition, the upper portion of the first contact plug 53-1 is exposed by the spacer formation process.

As illustrated in FIG. 6d, a first capacitor 61 including a storage node electrode 58, a dielectric film 59 and a plate electrode 60 is formed to contact the exposed first contact plug 53-1. Here, the first capacitor 61 has the same height as the third contact plug 53-3.

Referring to FIG. 6e, a second etch stop layer 62 and a third interlayer insulating film 63 are sequentially formed on the entire surface of the resulting structure, and a contact hole 64 for external connection of the plate electrode 64 is then formed therein.

As shown in FIG. 6f, a fourth contact plug 65 for plate electrode is formed to fill the contact hole 64. The third interlayer insulating film 63 is then removed to expose the second etch stop layer 62, and a second insulating spacer 66 is formed on the sidewalls of the fourth contact plug 65. Here, the second insulating spacer 66 has the same size restriction as the first insulating spacer 57. In addition, the upper portion of the third contact plug 53-3 is exposed by the spacer formation process.

As depicted in FIG. 6g, a second capacitor 70 including a storage node 67, a dielectric film 68 and a plate electrode 69 is formed to contact the third contact plug 53-3.

Each of the first capacitors 61 and the second capacitor 70 has a width of 2F and a length of 6F.

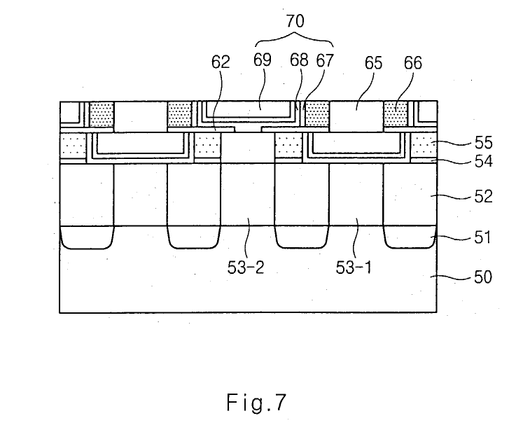

FIG. 7 is a cross-sectional view illustrating a semiconductor device in accordance with a third embodiment of the present invention.

Referring to FIG. 7, in insulation between the upper and lower capacitors using the first and second insulating spacers 57 and 66 is embodied by an additional photoetching process to remove a portion of the etch stop layer 62 to expose the upper portion of the contact plug 56 for second capacitor, and then performing subsequent processes.

As discussed earlier, in accordance with the present invention, the capacitor of the semiconductor device and the method for forming the same provide improved cell capacitance four times as large as those of conventional capacitors although the aspect ratio is maintained by stacking the cell capacitors, thereby lowering a data read/write error rate to improve yield, and increasing refresh time to reduce power consumption.

Moreover, it is possible to manufacture a low voltage, low power and high performance DRAM. When the structure in accordance with the present invention is employed to form a capacitor having the same capacitance as the conventional capacitors, the aspect ratio is reduced to 1/4, and the formation process of the device is simplified to improve the yield of the device.

As a result, the capacitor of the semiconductor device and the method for forming the same provides improved operational characteristics of the device, and thus increase the yield and productivity of the device, which results in a high integration density of the device.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalences of such metes and bounds are therefore intended to be embraced by the appended claims.

What is claimed is:

1. A semiconductor device having a folded bit line structure in which a first capacitor and a second capacitor are connected to one active region, wherein the first capacitor and the second capacitor are respectively formed at a different altitude, being electrically isolated from each other.

2. The semiconductor device according to claim 1, wherein the first and the second capacitors are 5F² respectively and overlaps each other by 1F².

3. A semiconductor device, comprising:
a 5F by 1F rectangular active region;
two word lines of 1F, running across one active region; and
two capacitors at a different altitude connected to one active region formed the two capacitors being electrically isolated from each other, wherein the two capacitors have a size of 5F² respectively and overlap by a predetermined size.

4. The semiconductor device according to claim 3, wherein the two capacitors overlap each other by F².

5. A semiconductor device, comprising:
a 5F by 1F rectangular active region;
two word lines of 1F, running across one active region; and
two 2F by 6F capacitors connected to one active region, wherein the two capacitors are formed at a different altitude and electrically isolated and overlap by a predetermined width.

6. The semiconductor device according to claim 5, wherein the two capacitors overlap each other by 2F×2F.

7. A method for forming semiconductor device, comprising the steps of:
forming a device isolation oxide film defining active regions on a semiconductor substrate;
forming a first interlayer insulating film on the entire surface of the resulting structure;
selectively patterning the first interlayer insulating film to form a first and a second contact plugs contact to the active region;
forming a third contact plug contacting the second contact plug;
forming a first insulating spacer on the sidewalls of the third contact plug, whereby a first contact hole exposing the first contact plug is generated;
forming a first capacitor having a storage node, a dielectric film and a plate electrode in the first contact hole;
forming a fourth contact plug connected to the plate electrode of the first capacitor on the resultant structure;
forming a second insulating spacer on the sidewalls of the fourth contact plug so that the second insulating spacer covers the exposed surface of the first capacitor, whereby a second contact hole exposing the third contact plug is generated; and
forming a second capacitor in the second contact hole.

8. The method according to claim 7, further comprising, after forming the first capacitor, a step of forming a second insulating film on the resultant structure to isolate the first capacitor from the second capacitor.
